(19) United States
(12) Patent Application Publication
(10) Pub. No.: US 2015/0047674 A1
(43) Pub. Date: Feb. 19, 2015

(54) METHOD AND APPARATUS FOR REMOVAL OF PHOTORESIST USING IMPROVED CHEMISTRY

(71) Applicant: TEL NEXX, Inc., Billerica, MA (US)

(72) Inventors: Daniel L. Goodman, Lexington, MA (US); Mani Sobhian, Chelsmford, MA (US); Arthur Keigler, Wellesley, MA (US)

(73) Assignee: TEL NEXX, Inc., Billerica, MA (US)

(21) Appl. No.: 13/969,264

(22) Filed: Aug. 16, 2013

(51) Int. Cl. H01L 21/02; B08B 3/14; B08B 3/10

(52) U.S. Cl. CPC H01L 21/02041; B08B 3/102; B08B 3/14
USPC 134/10; 134/34; 134/111

(57) ABSTRACT

Techniques disclosed herein include a method and apparatus for stripping resist from a substrate without using high concentrations of toxic chemicals and without needing frequent bath replacement. Techniques include using a chemistry that lifts-off the resist, without substantially dissolving the resist, coupled with mechanically breaking removed resist into small particles using mechanical agitation and high fluid flow. Resist particles can then be removed from the vicinity of the wafer by a high-flow circulation out of a processing tank. Circulating flow can then be filtered to remove the resist particles from the circulating fluid and reintroduced into the processing tank. A filtering system can also remove particles from filters either during circulation or with circulation stopped.

### BACKGROUND OF THE INVENTION

The present invention relates to substrate processing including processing of semiconductor substrates and wafers.

When processing a semiconductor wafer by, for example, a photolithographic process, a photoresist film is formed on a surface of the wafer. The surface of the wafer coated with the resist film is exposed to light in a desired pattern. Afterwards, the exposed wafer is subjected to a developing process to develop an image of the pattern by removing portions of the resist. These portions to be removed can either be portions of resist exposed to the light or shielded from the light depending on whether a positive tone resist or a negative tone resist is used.

A cleaning apparatus can be used for removing the unnecessary portions of the resist film. The cleaning apparatus can use various spray or immersion techniques to remove the unnecessary portions. The result is a patterned resist mask that can be used for various subsequent fabrications steps. For example, one or more plasma etching steps can transfer the pattern in the resist to an underlying layer. Eventually the patterned resist mask or layer needs to be cleaned or removed from the wafer to continue fabrication, which may include additional photolithography steps and thus resist patterning, partial removal, and full removal can be repeated.

### SUMMARY

Conventional techniques for removing resist, including removal of relatively thick resists for advanced packaging applications, include using either a spin bowl system or a dipping tank. In either apparatus, removal involves using a chemistry that fully dissolves the resist. Fully dissolving the resist is a conventional technique to prevent re-deposition of resist residue as well as to prevent clogging filters with resist.

Conventional stripping chemistry and techniques have disadvantages. For example, conventional chemistry that fully dissolves resists acts by chemically reacting with the resist. This reaction causes chemical changes to the resist strip chemistry itself, which reduces the stripping effectiveness. As a result, a bath containing fully dissolving chemistries are limited to a number of wafers that can be processed before the bath becomes ineffective and needs to be completely replaced. Fully replacing a chemistry bath can be costly. Another disadvantage of conventional stripping chemistries is that such chemistries are highly toxic. A common fully-dissolving resist strip chemistry contains tetramethyl ammonium hydryoxide (TMAH) in relatively large concentrations. TMAH is often combined with dimethyl sulfoxide (DMSO) to penetrate a resist polymer. Such chemistries pose a danger to workers and are expensive to dispose of after use. Thus, it would be desirable to have a resist strip apparatus and process that is not limited by the reaction between the chemistry and photoresist. It would also be desirable to replace toxic chemistry with less toxic “green” chemistry or relatively safer chemistry.

Techniques disclosed herein include a method and apparatus for stripping resist from a substrate without using high concentrations of toxic chemicals and without needing frequent bath replacement. Techniques include using a chemistry that lifts off the resist, without substantially dissolving the resist, coupled with mechanically breaking sheets of removed resist into small particles using mechanical agitation. Resist particles can then be removed from the vicinity of the wafer by a high-flow circulation out of a processing tank. Circulating flow can then be filtered to remove the resist particles from the circulating fluid and reintroduced into the processing tank. A filtering system can also remove particles from filters either during circulation or with circulation stopped.

One embodiment includes a method of removing a resist film from a substrate. This method can include preparing a liquid bath in a processing tank. The liquid bath includes a lift-off chemistry that reduces adhesion of a given resist layer to a given surface when the lift-off chemistry is in fluid contact with the given resist layer. A substrate, having a resist film, is disposed in the liquid bath that includes the lift-off chemistry. The liquid bath is physically agitated sufficiently such that the resist film separates from the substrate and is mechanically broken into resist particles with less than about 10% of the resist film dissolving in the liquid bath. The liquid bath is flowed out of the processing tank carrying the resist particles in the flow. The resist particles can then be filtered from the liquid bath so that the liquid bath can be returned to the processing tank for reuse.

Another embodiment includes an apparatus for removing a resist film from a substrate. This apparatus can include several components. A processing tank is configured to hold a liquid bath. A plurality of substrate holders are configured to hold a plurality of substrates within the processing tank such that the plurality of substrates are submerged when the liquid bath fills the processing tank. An array of agitation members are positioned within the processing tank with each agitation member including a shear plate. Each shear plate is positioned adjacent to a respective substrate holder such that each shear plate maintains a predetermined distance from a surface of a respective substrate when the plurality of substrates are held within the processing tank. The array of agitation members is connected to an agitation mechanism configured to move each shear plate and create turbulent fluid flow at surfaces of the plurality of substrates. A connected circulation system is configured to flow a liquid bath from a fluid outlet in the processing tank, through a filtration system, and into the processing tank via a fluid inlet. The filtration system can include two or more flow paths so that filters can be cleaned without stopping circulation.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIG. 1 is a schematic diagram that shows instrumentation and process flows of a resist removing apparatus according to embodiments disclosed herein.

FIG. 2 is a schematic diagram of a filtration system component of a resist removing apparatus according to embodiments disclosed herein.

FIG. 3 is a schematic diagram of a filtration unit of a resist removing apparatus according to embodiments disclosed herein.

FIG. 4 is perspective view of a plurality of substrate holders that are holding substrates according to embodiments herein.

FIG. 5 is a perspective view of an array of agitation members and shear plates according to embodiments herein.

FIG. 6 is flow chart of an example process for removing a resist film from a substrate according to embodiments herein.

### DETAILED DESCRIPTION

Techniques disclosed herein include a method and apparatus for stripping resist from a substrate without using high concentrations of toxic chemicals and without needing frequent bath replacement. Techniques include using a chemistry that lifts off the resist, without substantially dissolving the resist, coupled with mechanically breaking sheets of removed resist into small particles using mechanical agitation. Resist particles can then be removed from the vicinity of the wafer by a high-flow circulation out of a processing tank. Circulating flow can then be filtered to remove the resist particles from the circulating fluid and reintroduced into the processing tank. A filtering system can also remove particles from filters either during circulation or with circulation stopped.

Semiconductor fabrication routinely involves creating patterned resist films, and then removing the resist films after using a given pattern. Thick resist films and negative resist films are often used in packaging applications and other high-aspect ratio applications. These thick resist films, however, can be very difficult to remove. Conventional techniques involve using a chemistry that dissolves the resist, but this chemistry is highly toxic. For example, conventional chemistry can contain 5% TMAH and 80% DMSO. Moreover, the longer wafers remain in such a dissolving chemistry, the greater chance there is for metal corrosion.

Techniques herein provide a process and apparatus for removing resist films using a “green” or substantially less toxic chemistry as compared to the conventional chemistries that dissolve resists. Chemistry that lifts off resist without dissolving is available from several chemical companies including Dyanaloy of Indianapolis, IN and Air Products of Allentown, Pa. These lift-off chemistries can contain materials that infiltrate the polymer chain and cause swelling of the polymer and reduced adhesion to surfaces. In other words, such lift-off chemistries function by enabling a given resist film to be peeled off or to be separated from a given surface. A given lift-off chemistry can contain constituent ingredients selected to target a specific type of resist. By way of a non-limiting example, lift-off chemistries can be comprised of mixtures of protic organic solvents with additional solvents containing Lewis bases, which can include compounds containing a nitrogen group such as amines, imides, or amides either dissolved or substituted. Alternatively, the lift-off chemistries can be a high-pH aqueous-based solution. In general, the chemistry used can be formulated and optimized to remove a particular photoresist.

Techniques herein combine this lift-off chemistry with aggressive agitation, which causes the resist to peel off in layers or clumps, sometimes rolling into balls and then breaking into smaller mechanical particles. Techniques herein include using a relatively strong current flowing over or across the wafer. This strong current, coupled with aggressive agitation, helps to break the resist into particles and helps to prevent re-deposition of resist particles. Note that lift-off chemistries that cause reduced adhesion to a surface are different than chemistries that cause a resist to gel, which is indicative of partial dissolution.

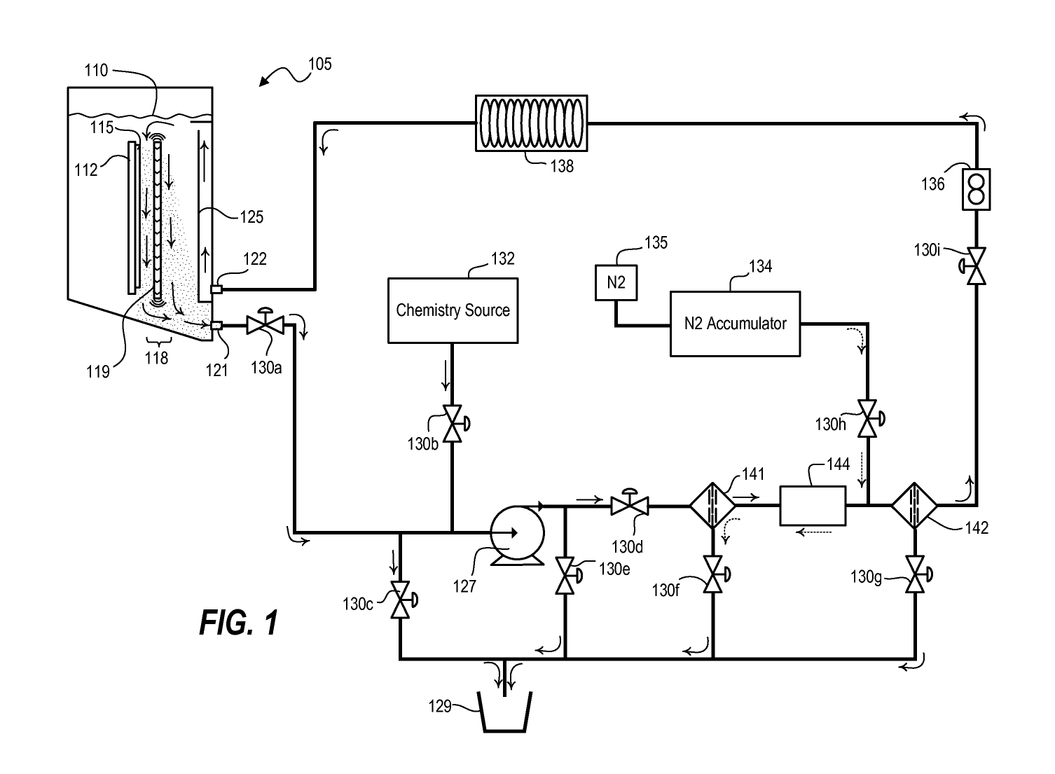

Referring now to FIG. 1, an example apparatus for removing a resist film from a substrate is illustrated in a schematic diagram. The apparatus includes several features and components. A processing tank 105 is configured to hold a liquid bath 110. A plurality of substrate holders 112 is configured to hold a plurality of substrates 115 within the processing tank 105 such that the plurality of substrates 115 is submerged when the liquid bath 110 fills the processing tank 105. An array of agitation members 118 is positioned within the processing tank 105. Each agitation member 118 includes a shear plate 119, with each shear plate positioned adjacent to a respective substrate holder 112 such that each shear plate 119 maintains a predetermined distance from a surface of a respective substrate when the plurality of substrates 115 is held within the processing tank 105. The array of agitation members 118 can be connected to an agitation mechanism (not show) configured to move each shear plate and create turbulent fluid flow at surfaces of the plurality of substrates. For example the agitation mechanism can cause the shear plate to move up and down rapidly. The shear plate can include physical features, such as fins, that create turbulence when rapidly moved within the liquid bath 110.

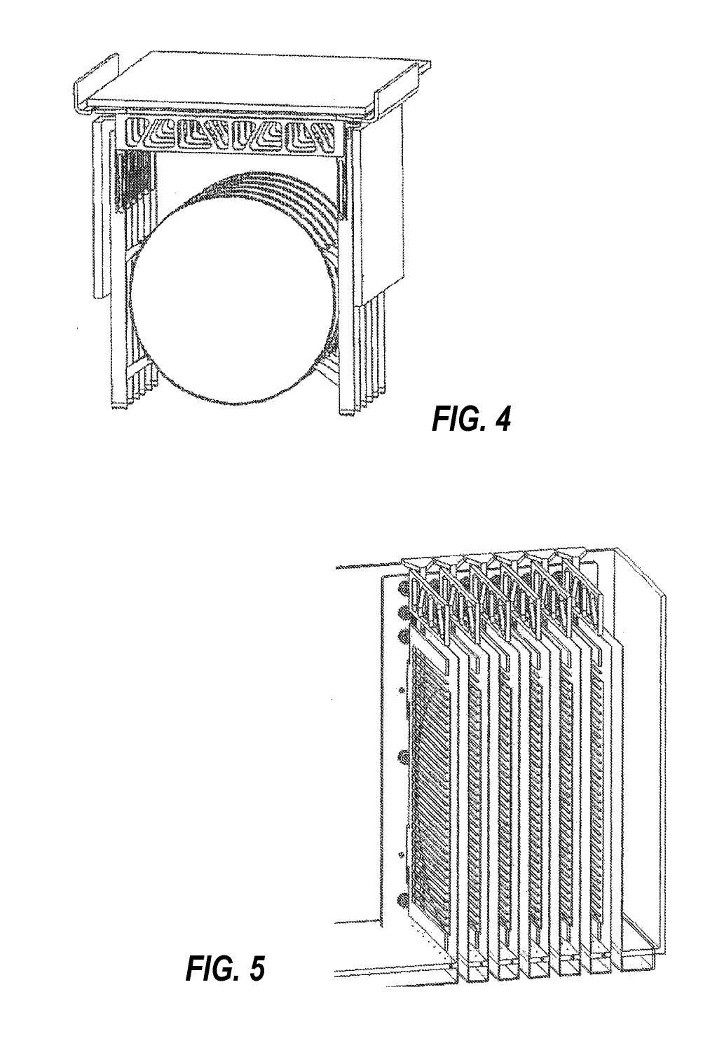

FIG. 1 illustrates the plurality of substrate holders and array of agitation mechanisms as a single holder and single shear plate for convenience in describing embodiments. The resist removal apparatus and method can function using a single substrate holder, substrate, and shear plate for effective resist removal. Throughput, however, can be increased by executing resist removal operations as a batch process. FIG. 4 is a perspective view of an example plurality of substrate holders with each holder holding a respective substrate. FIG. 5 shows an example array of agitation members and shear plates. Note that each shear plate is positioned parallel to the remaining shear plates, with each shear plate positioned a predetermined distance from an adjacent shear plate. This gap between shear plates enables the plurality of substrate to be positioned between the array of shear plates. Various guides can structures can be used to prevent the shear plates from physically contacting surfaces of the substrates. A more detailed description of that array of agitation mechanisms and plurality of substrate holders can be found in U.S. Patent Application Publication Number 2012-0305193, entitled “Parallel Single Substrate Processing Agitation Module,” and filed on Jun. 4, 2012, this publication is hereby incorporated by reference in its entirety.

The apparatus can include a circulation system. The circulation system can be configured to flow a liquid bath from a fluid outlet 121 in the processing tank 105, through a filtration system, and into the processing tank 105 via a fluid inlet 122. The circulation system can include multiple conduits and valves 130. The processing tank and circulation system can be configured to create a fluid down-flow when the circulation system is circulating the liquid bath. For example, pump 127 creates a fluid flow from fluid outlet 121 to fluid inlet 122. The processing tank 105 can include a flow plate 125, or other fluid management structures, that guide the fluid in the tank and cause the fluid within the processing tank to have a generally downward flow path across the shear plate 119 and substrate 115. In some embodiments the flow rate can be relatively high and sufficient to assist in breaking a resist film into particles. The high flow rate can also prevent re-deposition of resist particles on the substrate surface. This high flow rate helps to move resist particles out of the processing tank. Note that this down-flow does not need to be limited to a top to bottom flow, but can be a bottom to top or side to side flow.

The circulation system can include various additional components. For example chemistry source 132 can be used to add addition chemistry and/or liquid bath fluid to the circulation system when depleted, such as by opening valve 130b. Note that valves 130 (with respective reference letters) can be opened or closed to modify flow paths and to add or remove fluid from the circulation system. The circulation system can include a flow meter 136 and one or more pressure sensors (not shown). A heater 138 can be used to maintain the liquid bath at a predetermined temperate, such as a temperature that is optimal for resist removal.

The filtration system can be integrated with the circulation system. The filtration system can include one or more filters for trapping the resist particles and removing the resist particles from the liquid bath. Any number of filters can be used. The example of FIG. 1 uses a two filter system. There is a first (coarse) filter 141 and a downstream second (fine) filter 142. The coarse filter can contain a metal mesh type membrane. As fluid flow carries resist particles out of the processing tank (via the circulating liquid bath), resist particles are first or primarily trapped by the coarse filter, and then remaining particles are removed using the fine filter. The fine filter is fine relative to the coarse filter in that the fine filter can trap particles that passed through the coarse filter without being trapped. By way of a non-limiting example, the fine filter can collect particles larger than approximately 1 micrometer (μm) in diameter, while the coarse filter collects particles larger than approximately 40 μm in diameter. The filters 141 and 142 can periodically be cleaned. One method is to manually change the filters. Although manual filter changing can be effective, such maintenance typically involves shutting down the resist removal apparatus (tool) while filters are changed, which means lower throughput and higher service and parts cost.

Techniques herein, however, include a self-cleaning filtration system. The self-cleaning mechanism includes a backflow mechanism configured to reverse flow of the liquid bath through a portion of the circulation system to clean a given filter, and empty the particles removed from the filter into a drain 129. In the example filtration system, only coarse filter 141 is cleaned via a backflow operation. This is because a given coarse filter can collect a majority of the resist particles. To execute the backflow operation, a gas accumulator 134 or other pressurized gas delivery system is used. A gas source 135 can supply gas, such as nitrogen, to the gas accumulator 134 at a pressure sufficient to create a backflow having enough force to dislodge resist particles from a filter. Prior to executing the backflow operations, specific valves can be closed, such as 130d, 130e, 130c, 130g, and 130i. Between the gas accumulator 134 and coarse filter 141 is a fluid unit 144. This can be a fluid holding section sized to hold a sufficient volume of the liquid bath for clearing the coarse filter 141 of trapped resist particles. By way of a non-limiting example, 0.5 to 1.5 liters can be contained in the fluid unit 144. Although pressurized gas is delivered to the filtration system the pressurized gas is primarily used to push fluid through the coarse filter 141 in a direction reverse to fluid flow in the circulation system. Valve 130f can be opened during the backflow operation so that fluid and accumulated resist particles (dislodged from the filter) flow toward drain 129. Upon completion of the backflow operation, the valves 130f and 130h are closed, and then valves 130i and 130d are opened so that liquid bath circulation can continue. The advantage of such a filter self-cleaning operation is that a relatively small portion of the entire liquid bath fluid was lost from the circulation system. In some applications, less than a liter or less than five or ten percent of the liquid bath is lost. Chemistry source 132 can replenish lost fluid and then the resist removal apparatus can continue resist removal with a new batch of substrates having a resist film to be removed with minimal loss of strip chemistry. In contrast with conventional techniques, such as resist dissolving chemistry, such a conventional bath would need to be entirely replaced prior to processing a subsequent batch of wafers, which dramatically increases cost of operation.

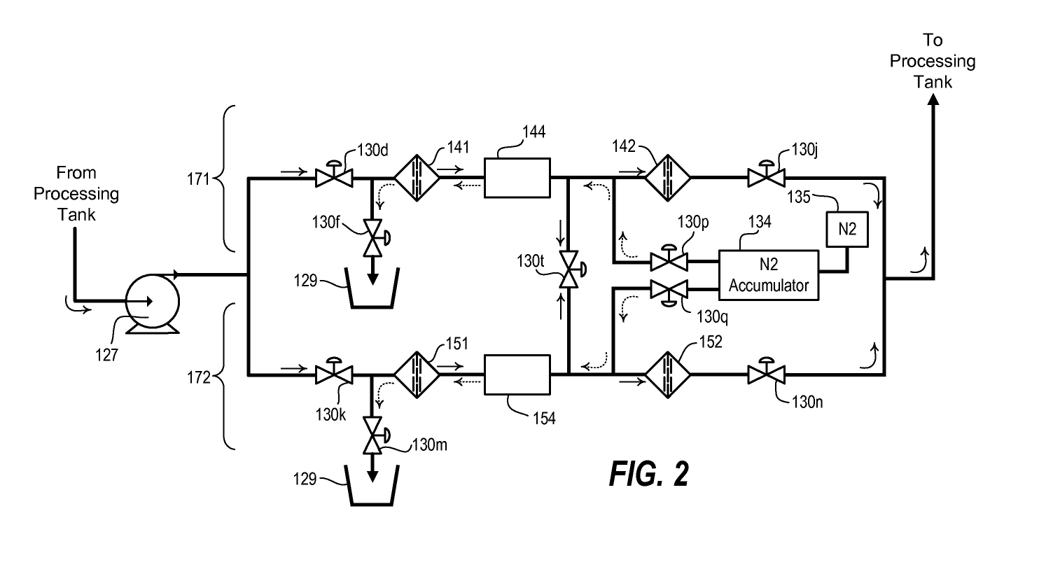

Referring now to FIG. 2, in other embodiments, the filtration system includes a valve mechanism that switches fluid flow from a first filtration flow 171 path to a second filtration flow path 172. Each filtration flow path includes a backflow mechanism configured to reverse flow of the liquid bath through one or more filters in a first flow path and into a corresponding drain while a second flow path maintains an open flow path. First filtration flow 171 path includes filtration components from FIG. 1. Second filtration flow path includes a duplicate set of components including coarse filter 151, fluid unit 154, and fine filter 152. Having two or more flow paths can increase system available because one flow path can be actively filtering a liquid bath during a resist removal operation while one or more filters are being flushed in an alternate flow path. In FIG. 2, valves 130d and 130k control flow to a respective flow path. In an example operation, flow path 172 needs filter 151 cleaned. For this filter cleaning, valves 130k, 130n, and 130t are closed. Valve 130m to drain 129 is opened. Upon opening valve 130q, pressurized gas pushes fluid contained in fluid unit 154 in a reverse direction through filter 151, thereby flushing accumulated resist particles out of the circulation system an into a fluid waste container. Fluid waste can flow to a correspond drain from the pressurized gas, using gravity, and/or a vacuum pump to help evacuate the drain line. After this backflow operation, liquid bath will be missing from flow path 172. Crossover valve 130t can then be opened to refill flow path 172 with liquid bath 110. Flow path 172 is now ready for filtering circulation. When flow path 171 is closed for filter cleaning, flow path 172 can be opened to maintain system availability. Note that the backflow flushing operation can be executed one or more times prior to reopening a given filter path depending on how much flushing a particular filter needs for sufficient cleaning.

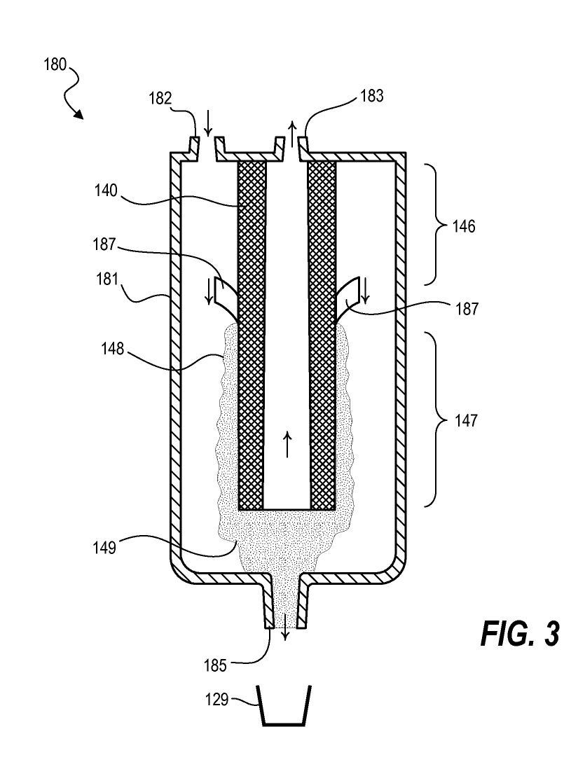

FIG. 3 shows an example filtration unit 180 that can be used with alternative embodiments. In general, filtration unit 180 shows an additional filter cleansing mechanism that can be used in addition to the backflow operation. This cleansing mechanism can include a scraping mechanism configured to scrape resist residue from a given filter and into a corresponding drain. Depending on a particular resist selected and a particular lift-off chemistry selected, there can be varying amounts of resist dissolving in the lift-off chemistry. By way of a non-limiting example, some resist and lift-off chemistry combination may have a 1% of the resist being dissolved, while other combinations may have 10% dissolved. With the relatively higher amounts of resist being dissolved, the resist can become a gel-like residue which can clog the filters. A given backflow operation can typically be more effective removing un-dissolved resist particles from a filter. Dissolved or partially dissolved resist can form a gel-like substance that sticks to a filter. Removal of this gel-like resist can be accomplished by manual or automated scraping.

FIG. 3 shows a cross-section of an example automated scraping mechanism to physically remove any resist residue that clings to the filter surface. Filtration unit 180 includes a filter housing 181 that contains filter element 140. Filter element 140 traps resist particles and resist gel flowing within the liquid bath through the circulation system. The liquid bath enters via inlet 182, passes through filter element 140, and exits via outlet 183. Resist gel residue 148 is shown clinging to section 147 of filter element 140. This resist gel residue 148 is removed from filter element 140 via scraper blade ring 187. Scraper blade ring 187 is shown moving in a downward direction in this example figure. Scraper blade ring 187 may be coupled to external motion control either directly through o-ring seals, or indirectly, for example via magnetic coupling. Note that above scraper blade ring 187 section 146 of filter element 140 is a cleaned region of the filter element 140 with no resist gel shown. As scraper blade ring 187 moves across the filter element 140, resist gel 149 is moved toward drain 129 via outlet 185. This resist gel can then be removed from the circulation system, treated, and/or otherwise discarded.

Note that this scraping operation can be combined with the backflow operation or executed separately. Filter scraping (resist removal via physical contact) can be executed as-needed or based on a predetermined schedule. Note that a scraper blade ring can be used for cylindrical filter elements, but this configuration is not limiting. For example, for planar filter elements, a linear scraper blade can be used. The filtration system is removable for occasional manual cleaning, but the combination of the backflow filter cleaning and mechanized filter element scraping can increase lifetime of a liquid bath, and substantially extend length between any manual cleaning and/or filter replacement.

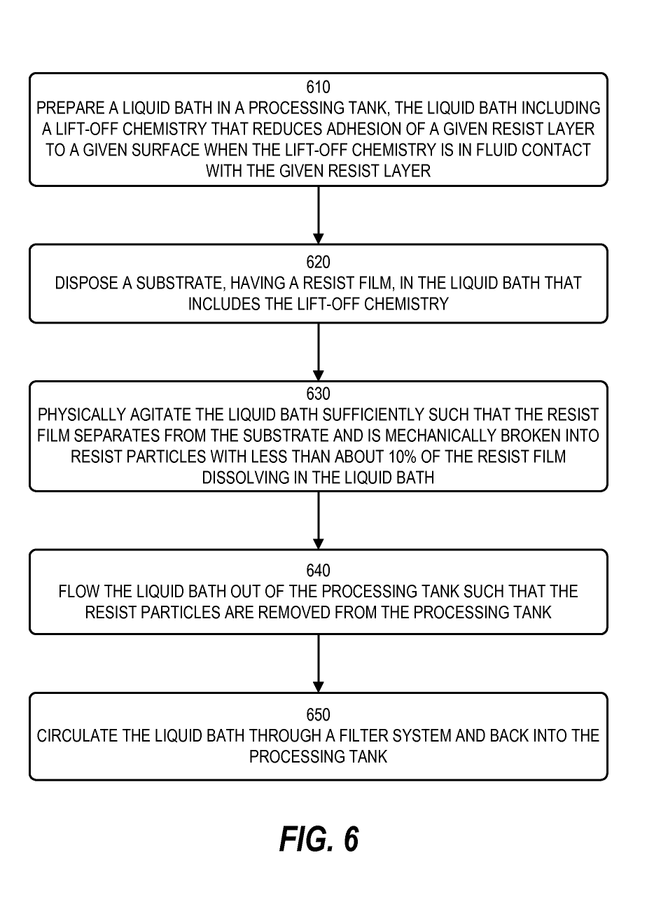

Referring now to FIG. 6, a flow chart discloses another embodiment that includes a method of removing a resist film from a substrate.

In step 610, a liquid bath is prepared in a processing tank. The liquid bath includes a lift-off chemistry that reduces adhesion of a given resist layer to a given surface when the lift-off chemistry is in fluid contact with the given resist layer. This liquid bath can be, for example, a strip chemistry that primarily operates by reducing adhesion of resist polymers to a surface on which the resist has been applied, such as by spin coating or dry application techniques. The mechanisms for reducing adhesion can depend on a particular resist selected from a chemical manufacturer. For example, some lift-off chemistries can swell or shrink the resist so that the resist peels off (or can be peeled off with physical agitation). The processing tank can be any tank configured to contain a resist strip chemistry, substrates, and agitation members. Embodiments can include processing tanks used in semiconductor manufacturing tools. In some embodiments, preparing the liquid bath can include the liquid bath having a concentration of tetramethyl ammonium hydryoxide (TMAH) that is less than about 3% or 2%. The liquid bath can also be prepared without adding DMSO. The liquid bath can be an aqueous or solvent-based solution.

In step 620, a substrate (or plurality of substrates), having a resist film, is disposed in the liquid bath that includes the lift-off chemistry. For example, a substrate holder and transportation mechanism moves one or more substrates from a storage container or pod to the processing tank. The resist film can be any conventional resist film such as positive tone or negative tone. The resist film can be a photoresist, extreme ultraviolet resist, or other radiation sensitive resist. At the time of the removal the resist film may have been exposed to radiation and no longer photo sensitive.

In step 630, the liquid bath is physically agitated sufficiently such that the resist film separates from the substrate and is mechanically broken into resist particles with less than about 10% of the resist film dissolving in the liquid bath. For example a shear plate or shear plate array is vigorously moved up and down (or side to side, etc.) such that the liquid bath in contact with the resist film develops a forceful or turbulent flow that assists in removing the resist film from the substrate and breaking the resist film into relatively small particles. The agitation member can also directly break detached resist film portions into particles.

In step 640, the liquid bath flows out of the processing tank such that the resist particles are removed from the processing tank. One or more pumps can assist in creating circulation.

In step 650, the liquid bath circulates or passes through a filter system and back into the processing tank. The filter system removed resist particles so that clean resist strip chemistry is returned to the processing tank and flowed across the substrate until the resist film is completely removed. Circulating the liquid bath through the filter system can include the filter system having a first flow path and a second flow path configured such that flow is switchable between the first flow path and the second flow path. Such a switchable flow path increases system availability. The first flow path and the second flow path can each include a first filter and a second filter, wherein the second filter is a finer filter relative to the first filter. With such a filter combination the first filter can trap a bulk of resist particles, depending on filter characteristics.

Methods can include cleaning at least one filter from a given flow path via a backflow operation. The backflow operation can include using air pressure to reverse flow of the liquid bath through a given filter and into a corresponding drain. The backflow operation can use a volume of the liquid bath that is less than about 10% of a total volume of the liquid bath in the processing tank and the filter system. In other words, a retained volume of the liquid bath in the processing tank after the backflow operation can be greater than about 90% as compared to a volume prior to the backflow operation. In addition to (or in place of) backflow filter cleaning, alternative methods can include cleaning at least one filter from a given flow path via a mechanical scraping operation. Either of these cleaning methods can be used with single flow path filtration systems, or filtration systems having multiple flow paths.

The circulation system can maintain a circulation flow greater than about 10 liters per minute in some embodiments, and greater than 30 liters per minute in other embodiments. Such a flow rate is dramatically greater than conventional resist strip methods. Circulating the liquid bath can include creating a down-flow circulation path of the liquid bath through the processing tank, such that fluid generally flows across the substrate surface is one direction.

In an alternative method of removing a resist film from a substrate, the method includes submerging a plurality of substrates in a bath. The substrates each have a resist film. The bath includes a lift-off chemistry that reduces adhesion of the resist film to each substrate. The bath is physically agitated via an array of agitation members. Each agitation member is positioned adjacent to a given substrate from the plurality of substrates such that the resist film is separated from each substrate and mechanically broken into resist particles with less than about 10% of the resist film dissolving in the bath. Depending on the resist strip chemistry, less than about 5% of the resist film dissolves in the bath. The bath and resist particles are then flowed out of a processing tank containing the bath and the plurality of substrates. The bath is circulated through a filtering system such that the bath exits the processing tank, passes through the filtering system and reenters the processing tank. This filtering system can include two or more separately controllable flow paths with corresponding backflow mechanisms.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to the object being processed in accordance with the invention. The substrate may include any material portion or structure of a device, particularly a semiconductor or other electronics device, and may, for example, be a base substrate structure, such as a semiconductor wafer, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method of removing a resist film from a substrate, the method comprising:
preparing a liquid bath in a processing tank, the liquid bath including a lift-off chemistry that reduces adhesion of a given resist layer to a given surface when the lift-off chemistry is in fluid contact with the given resist layer;
disposing a substrate, having a resist film, in the liquid bath that includes the lift-off chemistry;
physically agitating the liquid bath sufficiently such that the resist film separates from the substrate and is mechanically broken into resist particles with less than about 10% of the resist film dissolving in the liquid bath; and
flowing the liquid bath out of the processing tank such that the resist particles are removed from the processing tank.

2. The method of claim 1, wherein preparing the liquid bath includes the liquid bath having a concentration of tetramethyl ammonium hydryoxide (TMAH) of less than about 3%.

3. The method of claim 1, wherein flowing the liquid bath out of the processing tank includes circulating the liquid bath through a filter system and back into the processing tank.

4. The method of claim 3, wherein circulating the liquid bath through the filter system includes the filter system having a first flow path and a second flow path configured such that flow is switchable between the first flow path and the second flow path.

5. The method of claim 4, wherein the first flow path and the second flow path each include a first filter and a second filter, wherein the second filter is a finer filter relative to the first filter.

6. The method of claim 4, further comprising cleaning at least one filter from a given flow path via a backflow operation.

7. The method of claim 4, further comprising cleaning at least one filter from a given flow path via a mechanical scraping operation.

8. The method of claim 6, wherein the backflow operation includes using air pressure to reverse flow of the liquid bath through a given filter and into a corresponding drain.

9. The method of claim 8, wherein the backflow operation uses a volume of the liquid bath that is less than about 10% of a total volume of the liquid bath in the processing tank and the filter system.

10. The method of claim 8, wherein a retained volume of the liquid bath in the processing tank after the backflow operation is greater than about 90% as compared to a volume prior to the backflow operation.

11. The method of claim 8, wherein circulating the liquid bath includes maintaining a circulation flow greater than about 10 liters per minute.

12. The method of claim 11, wherein circulating the liquid bath includes maintaining a circulation flow greater than about 30 liters per minute.

13. The method of claim 8, wherein circulating the liquid bath includes creating a down-flow circulation path of the liquid bath through the processing tank.

14. The method of claim 1, wherein preparing the liquid bath includes preparing an aqueous solution.

15. The method of claim 1, wherein preparing the liquid bath includes preparing a solvent-based bath.

16. A method of removing a resist film from a substrate, the method comprising:
submerging a plurality of substrates in a bath, the substrates each having a resist film, the bath including a lift-off chemistry that reduces adhesion of the resist film to each substrate;
physically agitating the bath via an array of agitation members with each agitation member positioned adjacent to a given substrate from the plurality of substrates such that the resist film is separated from each substrate and mechanically broken into resist particles with less than about 10% of the resist film dissolving in the bath;
flowing the bath and resist particles out of a processing tank containing the bath and the plurality of substrates; and
circulating the bath through a filtering system such that the bath exits the processing tank, passes through the filtering system and reenters the processing tank.

17. An apparatus for removing a resist film from a substrate, the apparatus comprising:
a processing tank configured to hold a liquid bath;
a plurality of substrate holders configured to hold a plurality of substrates within the processing tank such that the plurality of substrates are submerged when the liquid bath fills the processing tank;
an array of agitation members positioned within the processing tank, each agitation member including a shear plate with each shear plate positioned adjacent to a respective substrate holder such that each shear plate maintains a predetermined distance from a surface of a respective substrate when the plurality of substrates are held within the processing tank, the array of agitation members connected to an agitation mechanism configured to move each shear plate and create turbulent fluid flow at surfaces of the plurality of substrates; and
a circulation system, the circulation system configured to flow a liquid bath from a fluid outlet in the processing tank, through a filtration system, and into the processing tank via a fluid inlet.

18. The apparatus of claim 17, wherein the filtration system includes a valve mechanism that switches fluid flow from a first filtration flow path to a second filtration flow path.

19. The apparatus of claim 18, wherein each flow path includes a backflow mechanism configured to reverse flow of the liquid bath through one or more filters in a first flow path and into a corresponding drain while a second flow path maintains an open flow path.

20. The apparatus of claim 17, wherein the filtration system includes a first filter and a backflow mechanism configured to reverse flow of the liquid bath through the first filter and into a corresponding drain.

21. The apparatus of claim 17, wherein the filtration system includes a first filter and a scraping mechanism configured to scrape resist residue from the first filter and into a corresponding drain.

22. The apparatus of claim 17, wherein the fluid outlet and fluid inlet are configured to create a fluid down-flow when the circulation system is circulating the liquid bath.
